(19) United States
(12) Patent Application Publication
(10) Pub. No.: US 2021/0135235 A1
(43) Pub. Date: May 6, 2021

(54) FILM MADE OF METAL OR A METAL ALLOY

(71) Applicant: Neutrino Deutschland GmbH, Berlin (DE)

(72) Inventor: Holger Thorsten Schubart, Berlin (DE)

(21) Appl. No.: 17/146,279

(22) Filed: Jan. 11, 2021

Related U.S. Application Data
(62) Division of application No. 15/555,595, filed on Sep. 5, 2017, now abandoned.

(30) Foreign Application Priority Data
Mar. 6, 2015 (DE) 10 2015 002 789.1
Nov. 17, 2015 (DE) 10 2015 014 721.8

(51) Int. Cl. H01M 4/66; G01T 1/00; H01L 21/02; H01L 31/115; H01L 31/072; H01L 31/028; H01M 4/04; H01M 4/134; H01M 4/36; H01M 4/38; H01M 4/583

(52) U.S. Cl. CPC H01M 4/661; Y02E 10/547; H01L 21/02527; H01L 21/0245; H01L 21/02532; H01L 21/02444; H01L 21/02507; H01L 31/115; H01L 31/072; H01L 21/02425; H01L 31/028; H01M 4/0423; H01M 4/134; H01M 4/366; H01M 4/386; H01M 4/583; G01T 1/00

(57) ABSTRACT

A film made of metal or a metal alloy, in particular a film made of aluminum or an aluminum alloy, a so-called NEUTRINO FILM or NTRINO FILM (registered trademarks), to a method of production and to a use of a film made of metal or a metal alloy.

The invention relates to a film made of metal or a metal alloy, in particular a film made of aluminum or an aluminum alloy, a so-called NEUTRINO FILM or NTRINO FILM (registered trademarks), to a method of production and to a use of a film made of metal or a metal alloy.

A considerable number of metal films, in particular aluminum films, are known from the prior art.

The object of the present invention is to further improve metal films, in particular aluminum films. These can then be used to convert nonvisible solar energy into direct current. This is effected in particular in that neutrino radiation is converted into energy.

This object is achieved according to a first aspect of the invention by a film made of metal or a metal alloy, wherein the film comprises a coating which comprises graphene and silicon. Additional materials are applied in a different sequence to the metallic carrier in different methods (coated by evaporation, sprayed, glued). The effect which is attained therewith is that kinetic energy of radiation (the nonvisible spectrum of solar radiation or spatial radiation such as e.g. neutrinos) is converted into current. This is effected by using a nanotechnologically modified lattice structure of the applied materials. The modified and compressed lattice structure serves as a braking medium (for example, doped graphene) which slows down the wave by approx 0.1%, in that molecules of the nonvisible spectrum of solar or space energy impact on molecules of the compacted lattice structure which does not occur in this way in nature. That pendulum movement is transferred in the next step to a conductor medium (e.g. silicon) and then to the carrier medium (e.g. aluminum, silver, gallium, etc.).

The metallic carrier or the metal alloy can be an established alloy. Advantageously, the film is made of silver, gold, copper, gallium or aluminum or one of its alloys, in particular a silver or gold alloy or an aluminum-gallium alloy. In this case, a film made of aluminum or an aluminum alloy has advantages in terms of cost. Better values are achieved with a film made of silver or a silver alloy.

An aluminum alloy can be an established aluminum metal alloy. For example, an aluminum-gold or aluminum-silver alloy is possible. Other aluminum alloys such as, for example, aluminum-manganese, or aluminum alloys with magnesium, copper, silicon, nickel, zinc, beryllium, and mixtures thereof are also possible.

It is particularly advantageous if the metal carrier of the film is made of an aluminum-gallium alloy or made of gold or silver, or a gold or silver alloy. The advantage of this is a higher conductivity, increasing the flow rate.

It is additionally advantageous if the film comprises a thickness of 0.01 mm to 4 mm, preferably of 0.01 mm to 1 mm, particularly preferably 0.05 mm-1 mm.

In addition, the coating can comprise approx. 10% to 80% silicon, preferably 10% to 50% silicon, particularly preferably 25% silicon.

Likewise, the coating can comprise 20% to 90% graphene, preferably 50% to 90% graphene, particularly preferably 75% graphene.

It is additionally advantageous if the coating comprises organic or inorganic adhesive components. Other established connection methods apart from gluing, for example including by application, are also advantageous.

The coating can be applied in individual layered substances or on the basis of a mixture. It is particularly advantageous if the nanotechnologically prepared substances are individually layered, as this creates a higher efficiency, meaning more current is generated.

It is particularly advantageous if the coating is a nanocoating, in which graphene and silicon are present as nanoparticles. In this case, the particles of the silicon should have a size of 5 nm to 500 nm, particularly preferably 5 nm, and those of the graphene should have a size of 20 nm to 500 nm, particularly preferably 20 nm, since the efficiency is increased the smaller the particles are.

The coating advantageously comprises alternate layers of silicon and graphene, in particular 10 to 20 silicon-graphene layers, in particular 12 silicon-graphene layers. In this case, 12 layers are particularly advantageous since the voltage decreases again after 12 layers.

In addition, the performance of the film can be increased if germanium, selenium, copper oxidal or tellurium is applied to the silicon. Additional experiments which increased the performance were carried out with tantalum, niobium, molybdenum and antimony.

The doping of the graphene plays an essential role in increasing the performance. In this case, both doping in a vacuum by means of ion implantation and a neutron transmutation doping can be carried out. In this case, doping can be carried out with the ions of the following particles: ferroniobium, nickel niobium, yttrium or samarium oxide. The area of the graphene is increased by a factor of 10\hat{ }6 with the aid of the doping, which results among other things in an increase in performance.

The coating should preferably take place in the absence of oxygen, since the oxidation effect occurs more rapidly depending on the doping. The result should be sealed even after the coating has been applied since the exclusion of air increases the stability.

Advantageously, 757 g of all materials are used on 1 km\hat{ }2. The metallic carrier constitutes the negative pole, the graphene the positive pole.

The films can be rolled or stacked during application in order to achieve the highest values. An A4 film can achieve 1 Watt; if the films are stacked to form a mobile power plant, a layer of insulation should be placed between the films.

The generation of current does not cause decomposition of the conductor. The conductor has a negative temperature coefficient. The optimum is 26.2 to 26.7° C.

The film can be used under the ground and in water and works better at night than by day.

A second aspect of the invention relates to a method for producing a film made of a metal or a metal alloy, in particular a film according to the invention, wherein a silicon layer is applied to the film, in particular by spraying or steaming, in a first step, the silicon layer is hardened, dried and purged with liquid nitrogen in a second step, a graphene layer is applied to the film in a third step and the graphene layer is hardened, dried and purged with liquid nitrogen in a fourth step.

Advantageously, germanium, selenium, copper oxidal, tellurium, tantalum, niobium, molybdenum and/or antimony is/are applied in a further step.

In an additional step, the graphene can be doped, in particular with ferroniobium, nickel niobium, yttrium or samarium oxide, in particular by ion implantation or by neutron transmutation doping.

A third aspect of the invention relates to a method for producing a film made of aluminum or an aluminum alloy, wherein graphene and silicon are pulverized and blended in a first step, and the pulverized graphene and silicon are applied to the film in a second step.

A fourth aspect of the invention relates to a method for producing a film made of aluminum or an aluminum alloy, in particular for producing a film according to the invention, wherein graphene and silicon are pulverized and blended in a first step, and an adhesive layer is applied to the film in a second step and the pulverized graphene and silicon are applied to the adhesive layer in a third step. Other established connection methods apart from gluing, for example including by application, are also advantageous.

A fifth aspect of the invention relates to a method for producing a film made of aluminum or an aluminum alloy, in particular for producing a film according to the invention, wherein graphene and silicon are pulverized and blended in a first step and an adhesive is blended with silicon and graphene powder in a second step and the mixture is applied to the film or fixed to the film in a third step. Other established connection methods apart from gluing, for example including by application, are advantageous.

A sixth aspect of the invention relates to a method for producing a film made of aluminum or an aluminum alloy, in particular for producing a film according to the invention, wherein an adhesive layer is applied to the film in a first step and a graphene and/or silicon layer is applied in a second step and a second adhesive layer is applied to the film in a third step and an additional silicon and/or graphene layer is applied to the film in a fourth step. Other established connection methods apart from gluing, for example including by application, are also advantageous.

A seventh aspect of the invention relates to a use of a film according to the invention for obtaining direct current from nonvisible solar energy.

The functional principle can be described in summary as follows:

Nature has relatively “wide-meshed” molecules so that the neutrinos fly through due to the low mass. Both the atoms in the molecules and the molecules in the substance structure therefore have to be closely “packed” so that a portion of the neutrinos cannot fly through without touching the particles.

The film surface therefore comprises nanotechnologically processed structures such that, in the same way as a mechanical pendulum chain, the molecules impact on one another and a flow of molecules and current flow (so-called channeling) therefore results from the mass and the kinetic energy.

This is to be understood in the same way as a current flow in a line: the molecules in the generator are set in motion by the magnet and coil, and we can therefore use the electricity.

The invention will be explained in greater detail below with reference to an embodiment example. Graphene and silicon are crushed in a mortar or otherwise pulverized (down to nanosize). An organic adhesive layer is applied to a commercially available aluminum film. The silicon and graphene powder is applied to said adhesive layer. The result is a film made of aluminum having a coating with a thickness of 0.1 mm or less. The ratio of the components graphene and silicon in the coating of the film is approx. 75% graphene and 25% silicon.

1. A method for obtaining direct current from nonvisible solar energy, the method comprising:
providing a film made of a metal carrier of a metal or a metal alloy with a coating of at least graphene and silicon, wherein the coating is a nano-coating in which graphene and silicon are present as nanoparticles, wherein the coating has at least one of 10% to 80% silicon and 20% to 90% graphene, wherein the lattice structure of the nano-coating is compressed such that kinetic energy from collisions of passing neutrinos of the nonvisible spectrum of solar energy with molecules of the nano-coating produce direct current that can be tapped with the nanoparticle coating as positive terminal and the metallic carrier as negative terminal,
tapping the nanoparticle coating as positive terminal and the metallic carrier as negative terminal, and
exposing the film to nonvisible solar energy such that kinetic energy from collisions of passing neutrinos of the nonvisible spectrum of solar energy with molecules of the nano-coating produce direct current.

2. The method according to claim 1, wherein the metal carrier is at least one of silver, gold, copper, gallium or aluminum or one of their alloys.

3. The method according to claim 1, wherein the metal carrier is at least one of a silver or gold alloy or an aluminum-gallium alloy.

4. The method according to claim 1, wherein the film has a thickness of 0.01 mm to 4 mm.

5. The method according to claim 1, wherein the film has a thickness of 0.01 mm to 1 mm.

6. The method according to claim 1, wherein the coating comprises 10% to 50% silicon.

7. The method according to claim 1, wherein the coating comprises 25% silicon.

8. The method according to claim 1, wherein the coating comprises 50% to 90% graphene.

9. The method according to claim 1, wherein the coating comprises 75% graphene.

10. The method according to claim 1, wherein the coating comprises organic or inorganic adhesive components.

11. The method according to claim 1, wherein the particles of silicon have a size of 5 nm to 500 nm and the particles of the graphene have a size of 20 nm to 500 nm.

12. The method according to claim 1, wherein the coating has alternating layers of silicon and graphene.

13. The method according to claim 12, wherein the alternating layers of silicon and graphene are 10 to 20 layers of silicon-graphene.

14. The method according to claim 1, wherein the coating comprises germanium, selenium, copper oxide, tellurium, tantalum, niobium, molybdenum and/or antimony.

15. The method according to claim 1, wherein the graphene is doped.

16. The method according to claim 1, wherein the graphene is doped with ferroniobium, nickel niobium, yttrium or samarium oxide.

17. The method of claim 1, wherein in the step of providing a film:
in a first step, a silicon layer is applied to the carrier,
in a second step, the silicon layer is hardened, dried and rinsed with liquid nitrogen,
in a third step, a graphene layer is applied to the film, and
in a fourth step, the graphene layer is cured, dried and rinsed with liquid nitrogen.

18. The method of claim 17, wherein the silicon layer is applied to the carrier by spraying or steaming.

19. The method of claim 17, wherein in a further step germanium, selenium, copper oxide, tellurium, tantalum, niobium, molybdenum and/or antimony is applied.

20. A film for obtaining direct current from nonvisible solar energy, the film made of a metal carrier of a metal or a metal alloy with a coating of at least graphene and silicon, wherein the coating is a nano-coating in which graphene and silicon are present as nanoparticles, wherein the coating has at least one of 10% to 80% silicon and 20% to 90% graphene, wherein the lattice structure of the nano-coating is compressed such that kinetic energy from collisions of passing neutrinos of the nonvisible spectrum of solar energy with molecules of the nano-coating produce direct current that can be tapped with the nanoparticle coating as positive terminal and the metallic carrier as negative terminal.
